(19) United States
(12) Patent Application Publication
(10) Pub. No.: US 2024/0295610 A1
(43) Pub. Date: Sep. 5, 2024

(54) METHODS AND SYSTEMS FOR SAFETY MONITORING OF RECHARGEABLE LITHIUM BATTERY POWERING ELECTRICAL DEVICE

(71) Applicant: GM Global Technology Operations LLC, Detroit, MI (US)

(72) Inventors: Niles A. Fleischer, Rehovot (IL); Alex Nimberger, Kiryat Ono (IL)

(73) Assignee: GM Global Technology Operations LLC, Detroit, MI (US)

(21) Appl. No.: 18/439,215

(22) Filed: Feb. 12, 2024

Related U.S. Application Data
(60) Provisional application No. 63/449,443, filed on Mar. 2, 2023.

(51) Int. Cl. G01R 31/3842; G01R 31/36; G01R 31/367

(52) U.S. Cl. CPC G01R 31/3842; G01R 31/3646; G01R 31/3648; G01R 31/367

(57) ABSTRACT

Method and system for safety monitoring of a rechargeable lithium battery powering an electrical device. Primary parameters of battery are measured during a normal operation of the electrical device. Primary parameters may include: DC current; DC voltage; state of charge; measurement timestamps; battery temperature and ambient temperature. Primary parameters are processed to derive secondary parameters, and to determine a state of risk (SOR) of battery based on primary parameters and secondary parameters, during normal operation of electrical device. Processing may apply resistors-capacitors model and/or machine learning model. SOR determination may be based on comparison with baseline value reflecting baseline condition of battery. SOR may include categories of No Fault Found (NFF); Potential Fault Found (PFF); and Fault Found (FF). Alert of a potential short circuit derived hazard may be provided and/or countermeasure may be implemented responsive to determined SOR, such as when SOR category is PFF or FF.

### CROSS-REFERENCE TO RELATED APPLICATIONS

This patent application claims the priority date benefit of U.S. Provisional Application No. 63/449,443 filed Mar. 2, 2023, the contents of which is incorporated herein by reference.

### TECHNICAL FIELD

The present disclosure relates to batteries and consumer safety in general, and to diagnostic tools for monitoring the safety of lithium-ion batteries in particular.

### INTRODUCTION

A rechargeable lithium battery is a type of rechargeable battery commonly used in electronic products. Lithium batteries are characterized by very high energy density relative to other types of rechargeable batteries, for example more than double that of some nickel-metal hydride cells. A lithium-ion cell typically includes a metal oxide, sulfur, iron phosphate based, or air cathode; usually a graphite based (sometimes in combination with varying amounts of silicon) or carbon based, lithium titanate, anode; and an electrolyte from organic solvents. The anode and cathode undergo reversible reactions with lithium ions during charging and discharging. Rechargeable lithium batteries are also valued for high power density, quality performance over a broad range of temperatures, and low self-discharge rate. Moreover, rechargeable lithium batteries are adaptable for use in a variety of cell designs and configurations (e.g., prismatic, cylindrical, flat, coin or pouch designs), as well as with both liquid organic electrolytes, solid state electrolytes, and polymer electrolytes.

Rechargeable lithium batteries are also known for their susceptibility to combusting or exploding under certain conditions. This phenomenon is typically caused by electrical faults, particularly from internal short circuits, which can develop from an accumulation of latent defects and/or operational defects. Latent defects may involve the presence of contaminants, or manufacturing deficiencies, which could lead to physical contact between the anode and the cathode or their respective current collectors. Operational defects may include, for example: the growth of lithium dendrites caused by lithium metal plating in the battery; the growth of copper dendrites caused by copper plating (when the battery cells use copper current collectors); tears or holes formed in the separator due to physical or thermal stresses that create an opportunity for the anode and cathode to come into physical contact; and manufacturing faults during cell assembly. Short circuits in the lithium battery cell may also result from degradation and environmental effects, such as physical impacts (e.g., falls or vibrations), large swings in temperature, physical shocks, and the like. An internal (or external) short circuit can trigger an exothermic chain reaction of the chemicals in the cell. This may lead to a rapid temperature increase which can decompose the electrolyte to produce flammable gases and a consequent buildup of pressure in the cell, causing the cell to swell or rupture, along with possible decomposition of metal oxide cathodes. The combination of generated heat, decomposition of the metal oxide cathode, and flammable components of the electrolyte (in a decomposed or original form) may lead to combustion or ignition of the cell, and in some cases explosion. The combustion may subsequently propagate to other battery cells in a multi-cell module or pack, causing the entire battery to explode or go up in flames.

The rapid self-heating of a cell driven by exothermic reactions of cell materials releasing stored energy, where the reactions are accelerated by the increased temperature, which in turn instigates a further temperature increase in a positive feedback loop, describes a process known as “thermal runaway”. At a critical temperature, thermal runaway may cause a sudden increase in cell temperature leading to combustion. When a short circuit develops, internal lithium battery cell temperatures can rise in just a matter of seconds to unsafe levels, thereby inducing thermal runaway and consequent combustion, which can propagate to surrounding cells. As rechargeable lithium batteries are more reactive and have poorer thermal stability compared to other types of batteries, they are more susceptible to thermal runaway in certain conditions. Such conditions may include: high temperature operation (e.g., above 80° C.) or overcharging (e.g., high rate charge at low temperatures); conditions that may produce internal shorts, such as lithium plating or copper plating; and/or manufacturing defects or defects resulting from use, misuse, or abuse. At elevated temperatures, cathode decomposition produces oxygen which reacts exothermically with organic material in the battery cell (e.g., flammable organic solvent electrolyte and carbon anode). The highly exothermic chain reaction is extremely rapid and can induce thermal runaway and reach excessive temperatures and pressures (e.g., 700° C. to 1000° C. and about 500 psi) in only a few seconds. Once the chain reaction begins it cannot effectively be stopped nor extinguished and will ultimately lead to combustion of the cell and (following the cell propagation effect) of the entire battery.

In summary, an initial internally developed fault or defect in a rechargeable lithium battery cell can trigger an internal short circuit, which in turn elicits heating and subsequently exothermic chain reactions, leading to irreversible thermal runaway and ultimately combustion/explosion. Cell heating from high environmental temperatures, rapid charging, high load discharging, and proximity between neighboring cells in a battery package, are factors that increase the potential for thermal runaway.

Serious safety hazards are thus posed by a wide range of rechargeable lithium battery powered devices, ranging from laptops and cellphones to electric or hybrid vehicles. There are frequent reports of dangerous incidents with such devices and numerous product recalls. The risk of such incidents is rising as the demands on the performance and size of cell and battery package increases, the cell energy density becomes greater, and rechargeable lithium batteries grow more prevalent in commercial products. Combustion of lithium battery cells may occur even under normal usage without prior warning. Consequently, some manufacturers avoid using lithium batteries in electrical products altogether, despite their many technical advantages.

There are various approaches for minimizing the likelihood of lithium battery combustion, such as employing diagnostic tools and ensuring proper storage and operating conditions. Some devices incorporate protection mechanisms for lithium batteries at the cell or battery package level to protect against over-charging, over-discharging, overheating, short-circuiting or other potentially dangerous conditions. For example, regulating mechanisms may terminate the battery current if certain operating limits are exceeded. However, the reaction time is [such reactive mechanisms are] generally insufficient for preventing combustion. Conventional systems typically track only basic cell parameters, such as operating current and voltage, resistance or impedance, and temperature, which only depict changes that become significantly detectable in the late stages of a developing short circuit when it is too late to avert the chain reactions that lead to irreversible thermal runaway and combustion. The complexity and required reaction speed increases significantly when a device includes a large number of battery cells connected in series or parallel, as each of the cells need to be individually monitored. Furthermore, a battery powered electrical device may be situated remotely or in a location with limited or difficult access, which can hinder the ability to monitor potential hazards in the battery.

### SUMMARY

In accordance with one aspect of the present disclosure, there is thus provided a method for safety monitoring of a rechargeable lithium battery powering an electrical device. The method includes the steps of measuring over time primary parameters of the battery, during a normal operation of the electrical device; processing the measured primary parameters to derive secondary parameters; and determining a state of risk (SOR) of the battery based on the measured primary parameters and the derived secondary parameters, during the normal operation of the electrical device. The primary parameters may include: a direct current (DC) current measurement; a DC voltage measurement; a state of charge (SOC) measurement; and a timestamp of each measurement. The primary parameters may further include at least one of: a battery temperature measurement; and an ambient temperature measurement. The step of processing may include at least one of: applying a resistors-capacitors model, configured to apply at least one mathematical operation or equation on the primary parameters; and applying a machine learning model, configured to apply at least one machine learning process on the primary parameters. The step of determining a state of risk (SOR) may include comparing at least one of the derived secondary parameters with a respective at least one baseline value reflecting a baseline condition of the battery. The step of determining a state of risk (SOR) may include determining a plurality of secondary parameter SORs, each of the secondary parameter SORs being associated with a respective one of the derived secondary parameters, and determining an overall battery SOR based on the plurality of secondary parameter SORs. The method may further include the step of providing an alert of a potential short circuit derived hazard, responsive to the determined state of risk. The method may further include the step of implementing at least one corrective measure to mitigate or prevent a short circuit derived hazard, responsive to the determined state of risk. The state of risk may include a state of risk category selected from the group consisting of: No Fault Found (NFF); Potential Fault Found (PFF); and Fault Found (FF), where at least one of the steps of providing an alert and implementing at least one corrective measure may be performed when the determined state of risk includes a state of risk category of PFF or FF. The state of risk may be determined in accordance with an adjustable sensitivity level reflective of at least one of: the battery; the electrical device; and an operating environment thereof. The electrical device may be selected from the group consisting of: an electrical vehicle (EV); a hybrid vehicle (HV); and a plug-in hybrid electric vehicle (PHEV).

In accordance with another aspect of the present disclosure, there is thus provided a system for safety monitoring of a rechargeable lithium battery powering an electrical device. The system includes at least one battery parameter detector, and a processor. The battery parameter detector is configured to measure over time primary parameters of the battery, during a normal operation of the electrical device. The processor is configured to process the measured primary parameters to derive secondary parameters, and to determine a state of risk of the battery based on the measured primary parameters and the derived secondary parameters, during the normal operation of the electrical device. The processor may be selected from the group consisting of: a processor of the electrical device; and a processor of a cloud computing server, communicatively coupled with the electrical device via a network. The battery parameter detector may include a detector selected from the group consisting of: a DC current detector, configured to measure a DC current of the battery; a DC voltage detector, configured to measure a DC voltage of the battery; a state of charge detector, configured to measure a state of charge of the battery; a clock, configured to provide a timestamp of each measurement; and a temperature sensor, configured to measure at least one of: a battery temperature; and an ambient temperature. The processor may apply at least one of: a resistors-capacitors model, configured to apply at least one mathematical operation or equation on the primary parameters; and a machine learning model, configured to apply at least one machine learning process on the primary parameters. The processor may be configured to determine a state of risk (SOR) based on a comparison of at least one of the secondary parameters with a respective at least one baseline value reflecting a baseline condition of the battery. The system may further include an application operating on a user computing device communicatively coupled with the processor via a network, the application configured to provide an alert of a potential short circuit derived hazard, responsive to the determined state of risk. The system may be configured to implement at least one corrective measure to mitigate or prevent a short circuit derived hazard, responsive to the determined state of risk. The state of risk may include a state of risk category selected from the group consisting of: No Fault Found (NFF); Potential Fault Found (PFF); and Fault Found (FF), where at least one of providing an alert and implementing at least one corrective measure may be performed when the determined state of risk includes a state of risk category of PFF or FF. The processor may be configured to determine a state of risk in accordance with an adjustable sensitivity level reflective of at least one of: the battery; the electrical device; and an operating environment thereof. The electrical device may be selected from the group consisting of: an electrical vehicle (EV); a hybrid vehicle (HV); and a plug-in hybrid electric vehicle (PHEV).

### BRIEF DESCRIPTION OF THE DRAWINGS

The present disclosure will be understood and appreciated more fully from the following detailed description taken in conjunction with the drawings in which:

FIG. 1 is a schematic illustration of a network environment supporting a computer-implemented system for detecting a safety hazard of a rechargeable lithium battery powering an unmanned electronic device, constructed and operative in accordance with an aspect of the present disclosure;

FIG. 2 is a schematic illustration of information flow in the system of FIG. 1, operative in accordance with an aspect of the present disclosure; and

FIG. 3 is a flow diagram of a method for detecting a safety hazard of a rechargeable lithium battery powering an unmanned electronic device, operative in accordance with an aspect of the present disclosure.

### DETAILED DESCRIPTION

The present disclosure overcomes the disadvantages of the prior art by providing methods and systems for detecting safety hazards in a rechargeable lithium battery powering an electrical device.

Unless otherwise defined, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the specification and claims and should not be interpreted in an idealized or overly formal sense unless expressly so defined herein. Well-known functions or constructions may not be described in detail for brevity and/or clarity.

It will be understood that, although the terms first, second, etc., may be used herein to describe various elements, components, regions, layers and/or sections, these elements, components, regions, layers and/or sections should not be limited by these terms. Rather, these terms are only used to distinguish one element, component, region, layer and/or section, from another element, component, region, layer and/or section.

It will be understood that when an element is referred to as being “on”, “attached” to, “operatively coupled” to, “operatively linked” to, “operatively engaged” with, “connected” to, “coupled” with, “contacting”, “added to, another element, it can be directly on, attached to, connected to, operatively coupled to, operatively engaged with, coupled with, added to, and/or contacting the other element or intervening elements can also be present. In contrast, when an element is referred to as being “directly contacting” another element or “directly added” to another element, there are no intervening elements and/or steps present.

Whenever the term “about” or “approximately” is used, it is meant to refer to a measurable value such as an amount, a temporal duration, and the like, and is meant to encompass variations (e.g., ±20%, ±10%, ±5%, ±1%, ±0.1%) from the specified value, as such variations are appropriate to perform the disclosed aspects.

Certain features of the present disclosure, which are, for clarity, described in the context of separate aspects, may also be provided in combination in a single aspect. Conversely, various features of the present disclosure, which are, for brevity, described in the context of a single aspect, may also be provided separately or in any suitable sub-combination or as suitable in any other described aspect of the present disclosure. Certain features described in the context of various embodiments are not to be considered essential features of those aspects, unless the aspect is inoperative without those elements.

Throughout this application, various aspects of the present disclosure may be presented in a range format. It should be understood that the description in range format is merely for convenience and brevity and should not be construed as an inflexible limitation on the scope of the present disclosure. Accordingly, the description of a range should be considered to have specifically disclosed all the possible subranges as well as individual numerical values within that range, regardless of the breadth of the range. Whenever a numerical range is indicated herein, it is meant to include any cited numeral (fractional or integral) within the indicated range.

Whenever terms “plurality” and “a plurality” are used it is meant to include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method aspects described herein are not constrained to a particular order or sequence. Additionally, some of the described method steps or elements thereof can occur or be performed simultaneously, at the same point in time, or concurrently.

Throughout, this disclosure may mention aspects or examples of disclosed systems or disclosed methods, which refer to examples of inventive ideas, concepts, and/or manifestations described herein. The fact that some disclosed aspects or examples are described as exhibiting a feature or characteristic does not mean that other disclosed aspects or examples necessarily share that feature or characteristic.

This disclosure employs open-ended permissive language, indicating for example, that some aspects or examples “may” employ, involve, or include specific features. The use of the term “may” and other open-ended terminology is intended to indicate that although not every aspect may employ the specific disclosed feature, at least one aspect employs the specific disclosed feature.

The term “battery” in general, and the terms “lithium battery” or “rechargeable lithium battery (RLB)” in particular, as used herein refers to any lithium based rechargeable battery containing any number of electrochemical cells (or groups of cells) connected in any configuration (e.g., series, parallel, and combinations of series and parallel), including also a single-celled battery, as well as encompassing all types of cell form factors (e.g., including but not limited to: cylindrical, prismatic, pouch, coin, and button cells), sizes, and cell designs (e.g., including but not limited to: jelly-roll design cells, bobbin cells, cells with Z-fold electrodes, cells with dog-bone folded electrodes, cells with elliptically folded electrodes, and parallel plate stacked electrode cells, whether bi-polar or not). A RLB generally includes at least a pair of electrodes (anode, cathode), an electrolyte for conducting lithium ions (liquid, solid, semi-solid and/or polymer), and a separator. The battery may be integrated with or form part of at least one electrical or electronic device or component (e.g., including but not limited to at least one of: a capacitor; a supercapacitor; a printed circuit board (PCB); a semi-conductor device, electronics, a passive electronic component, a battery management system; an electronic control unit; a power adapter; a charger; a wireless charging system; a fuse; a sensor; a positive temperature coefficient (PTC) device; a current interrupt device (CID); and any combination thereof). The terms “battery” and “battery pack” are used interchangeably herein. It is noted that “lithium battery” herein encompasses Li-metal rechargeable batteries, lithium-ion (Li-ion) rechargeable batteries, and Li-ion polymer rechargeable batteries, as well as these types of batteries as including but not limited to: reserve type batteries, thermal type batteries, so-called lithium-ion capacitors, and Li-air and Li-sulfur batteries. The present disclosure is applicable to all types of rechargeable lithium battery chemistries, including but not limited to cathodes whose active material is based on nickel manganese cobalt oxides (NMC), nickel cobalt aluminum oxides (NCA), lithium cobalt oxides (LCO), lithium ion manganese oxide (LMO), sulfur, and lithium iron phosphates (LFP) (each cathode in a range of effective stoichiometries), anodes whose active material is based on graphite, hard carbon, soft carbon, lithium titanate (LTO), lithium metal, silicon, silicon-carbon composites, silicon graphite composites, tin.

It is noted that the term “cell” generally refers to an individual battery cell, while the term “battery” typically refers to a plurality of cells, although may also refer to an individual cell. Multiple cells of a battery may be electrically connected in one or more groups, in parallel and/or in series. Such interconnected groups of cells may be assembled into cell modules, where multiple groups or modules may also be connected (in parallel and/or in series). A multi-celled battery or battery pack may be assembled from one or more cells, cell groups or modules, all of which are encompassed by the term “battery”.

The terms “fault”, “internal fault”, and “short-circuit precursor condition (SCPC)” are used herein interchangeably, and is defined as any condition that may lead to a (non-benign) internal short-circuit within at least one RLB cell, which in turn may lead to a number of possible undesirable outcomes. Accordingly, the term “short circuit derived hazard (SCDH)” refers herein to a possible undesirable outcome of a (hard) short circuit in at least one RLB cell. Examples of a short circuit derived hazard (SCDH) may include: i) exothermic chain reactions followed by thermal runaway and subsequent combustion; ii) unwanted self-discharge of a battery cell; iii) a battery cell remaining in a dormant benign SCPC state for an unknown period of time with an unknown probability of eventually developing into combustion; iv) actuation of a current interrupt device (CID) in a cell; and v) actuation of a safety pressure vent in a cell. The term “combustion” is used herein broadly to encompass all forms of destructive battery states following or caused by thermal runaway, including but not limited to a lithium battery and/or at least one cell thereof, undergoing, at least partially: combustion, ignition, a fire, explosion, enflaming, rupturing, leaking of electrolyte solution, swelling, venting, and the like.

The terms “user” and “operator” are used interchangeably herein to refer to any individual person or group of persons using or operating a method or system according to an aspect of the present disclosure, such as a person monitoring a safety hazard of a rechargeable lithium battery of an electrical device.

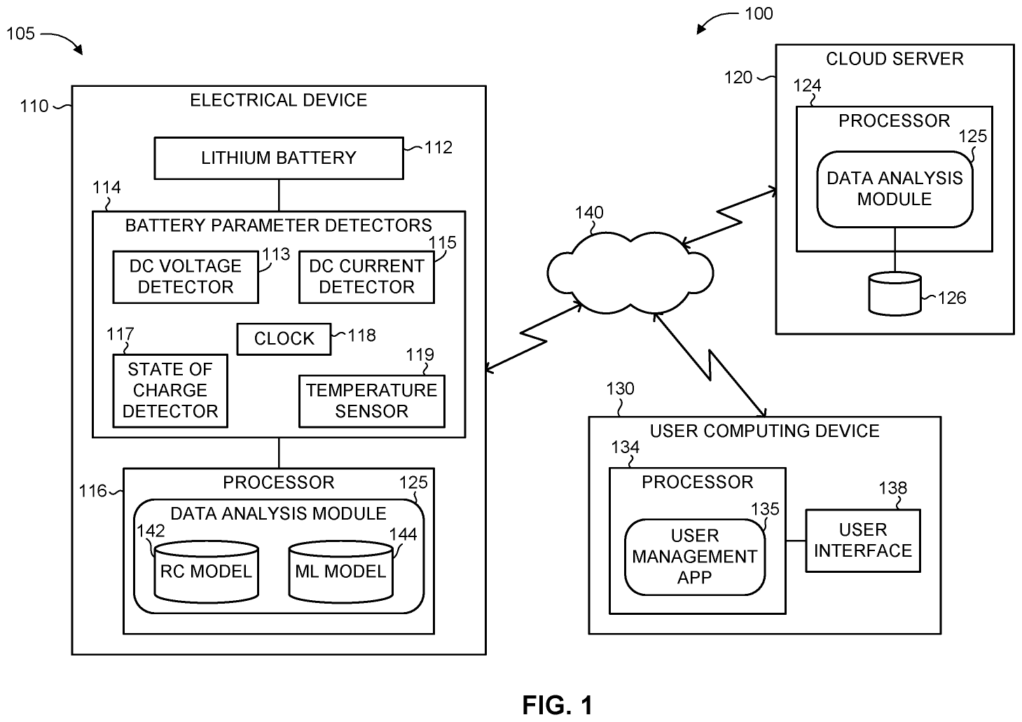

Reference is now made to FIG. 1, which is a schematic illustration of a network environment, generally referenced 100, supporting a computer-implemented system, generally referenced 105, for detecting a safety hazard of a rechargeable lithium battery powering an unmanned electronic device, constructed and operative in accordance with an aspect of the present disclosure. Network environment 100 includes at least one electrical device 110, at least one cloud server 120, and at least one user computing device 130. Electrical device 110 is powered by a lithium battery 112. Electrical device 110 further includes battery parameter detectors 114 and a processor 116. Cloud server 120 includes a processor 124 and a database 126. User computing device 130 includes a processor 134 and a user interface 138. System 105 includes battery parameter detectors 114, a data analysis module 125 operating on at least one of electrical device processor 118 and cloud server processor 124, and a user management application 135 operating on user device processor 134.

System 105 is configured to detect a safety hazard of lithium battery 112 of electrical device 110. An electrical device of the present disclosure may be any device that is electrically powered at least in part by at least one rechargeable lithium battery including any number of battery cells. Non-limiting examples of electrical devices may include: electric vehicles (EVs) or hybrid electric vehicles (HEVs) operating in any environment (e.g., air, land, or sea), such as automobiles, buses, vans, aircrafts, unmanned aerial vehicles (drones), maritime vessels, two-wheeled or three-wheeled electric/hybrid vehicles, plug-in hybrid electric vehicles (PHEVs), electric bicycles (e-bikes), and electric scooters (e-scooters); appliances; electronic devices; medical devices; mobile devices; computing devices; energy storage devices; uninterrupted power supplies; batteries for device charging; batteries for electric vehicle charging; satellites; robots; and the like.

Cloud server 120 may be associated with a cloud computing service. User computing device 130 is associated with a user of system 105, such as an operator of electrical device 110. User computing device 130 may be embodied by any type of electronic device with computing and network communication capabilities, including but not limited to: a smartphone; a laptop computer; a mobile computer; a tablet computer; or any combination of the above. User device 130 may be remotely located from electrical device 110 and from cloud server 120. Network environment 100 may include a plurality of user computing devices operated by multiple respective users, although a single user device 130 is depicted for exemplary purposes. Similarly, network environment 100 may include a plurality of remote servers, but a single cloud server 120 is depicted for exemplary purposes. Electrical device 110, cloud server 120, and user device 130 are communicatively coupled through at least one network 140. Accordingly, information may be conveyed between electrical device 110, cloud server 120, and user device 130, as well as to/from other networks communicatively coupled thereto, over any suitable data communication channel or network, using any type of channel or network model and any data transmission protocol (e.g., wired, wireless, radio, WiFi, Bluetooth, and the like), such as via a secured (e.g., encrypted) communication protocol. For example, collected data from electrical device 110 may be uploaded and dynamically processed in real-time in cloud server 120 using a cloud computing platform.

Battery parameter detectors 114 includes one or more devices or instruments configured to detect or measure electrical parameters or characteristics relating to lithium battery 112, including electrical states and operating modes. For example, battery parameter detectors 114 may include a DC voltage detector 113 for measuring a voltage of battery 112 (e.g., a voltmeter), and a DC current detector 115 for measuring a current of battery 112 (e.g., ammeter). Battery parameters detectors 114 may further include a state of charge (SOC) detector 117 for measuring a state of charge of battery 112, a temperature sensor 119 for measuring a temperature of battery 112 and/or an ambient temperature (e.g., a thermocouple, a semiconductor or silicon diode, or an optical pyrometer), and a clock 118 for providing timestamps of measured battery parameters. Further examples of battery parameter detectors 114 may include but are not limited to: a resistance meter, an impedance measuring device, a frequency response analyzer, an LCD meter, electronic circuitry, an acoustic sensor, a magnetic sensor, and the like (including instruments that incorporate, in whole or in part, at least one such device).

Server processor 124 performs data processing required by cloud server 120 and may receive instructions or information from other components of system 105 or network environment 100. Server database 126 stores relevant information that can be retrieved and processed by server processor 124. User device processor 124 performs data processing required by user device 130 and may receive instructions or data from other components of system 105 or network environment 100, such as from cloud server 120. Information may be stored in a local memory (not shown) of user device 130.

User interface 138 allows the user to receive information and to control parameters or settings associated with user device 130. For example, user interface 138 may include a display screen configured to present visual content, such as alerts issued by user management app 135. User interface 138 may include a cursor and/or a touch-screen menu interface, such as a graphical user interface, configured to enable manually entering instructions or data. User interface 138 may also include peripheral communication devices configured to provide audible communication, such as a microphone and an audio speaker, as well as voice recognition capabilities to enable the user to enter instructions or data by means of speech commands.

The components and devices of system 105 may be based in hardware, software, or combinations thereof. It is appreciated that the functionality associated with each of the devices or components of network environment 100 or system 105 may be distributed among multiple devices or components, which may reside at a single location or at multiple locations. For example, the functionality associated with any of processors 118, 124, 134 may be integrated or may be distributed between multiple processing units. For example, the functionality of data analysis module 125 may operate at least partially on electrical device 110 (e.g., on an integrated circuit chip embedded with electrical device) and at least partially on cloud server 120. Similarly, at least part of the functionality associated with user management app 135 may reside externally to user device 130. System 105 may optionally include and/or be associated with additional components or modules not shown in FIG. 1, for enabling the implementation of the disclosed subject matter.

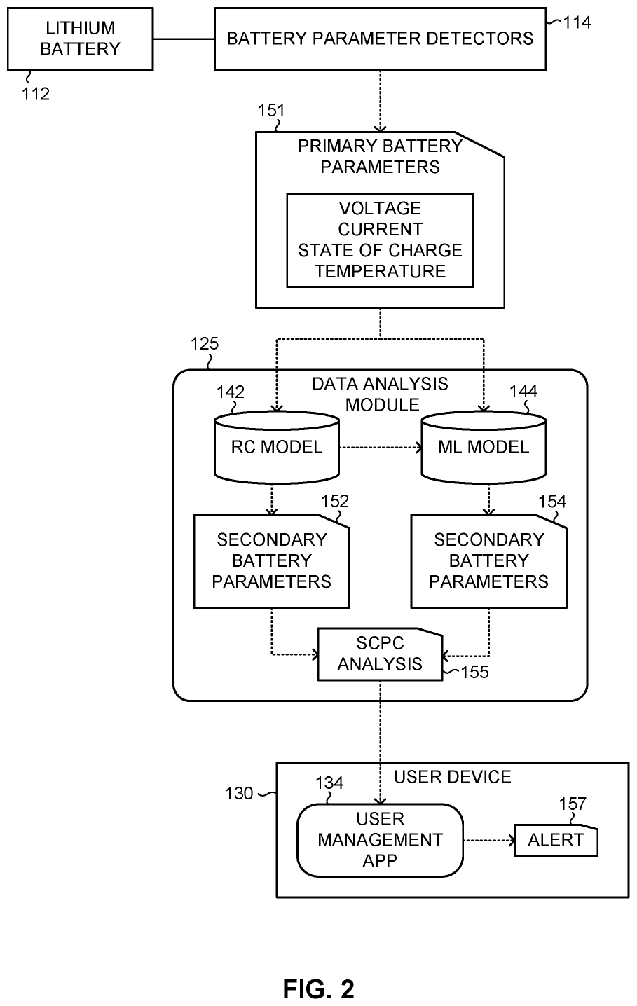

The operation of system 105 will now be described in general terms, followed by specific examples. Reference is further made to FIG. 2, which is a a schematic illustration of information flow in the system of FIG. 1, operative in accordance with an aspect of the present disclosure. Battery parameter detectors 114 measures or detects over a selected time period a set of battery parameters 151 of at least one cell of lithium battery 112 of electrical device 110. The measured battery parameters 151 may include: direct current (DC) voltage; DC current, a state of charge (SOC); and timestamps of parameter measurements. Time-variable battery parameters 151 may further include additional parameters, such as a temperature of battery 112 or an ambient temperature of electrical device 110. For example, DC voltage measurements may be obtained using voltage detector 113; DC current measurements may be obtained using current detector 115; SOC measurements may be obtained using SOC detector 117, and measurement timestamps using clock 118. SOC may be obtained from voltage measurements (e.g., during a calibration process), or from existing vehicle components for detecting battery SOC. Battery parameters 151 are measured or detected over a measurement time period and may be considered “time-variable” in that the parameter values may change over time, or alternatively may be constant throughout the measurement period.

Battery parameters 151 are obtained during a normal operation of electrical device 110. Normal operation may generally include any electrical activity associated with the operation of electrical device 110, such as during an electrical charging or discharging thereof. For example, electrical device may be an electric/hybrid vehicle and time-variable battery parameters 151 may be obtained when the vehicle is in a driving state. It is appreciated that a “driving state” or a state of normal operation in the case of a vehicle is not necessarily limited to vehicle motion or discharging of the battery during vehicle operation, but may also include periods of battery charging (such as regenerative charging) as well as discharging, including operations of “coasting” when the battery is not used for moving the vehicle, and operations of regenerative braking, and may further include periods of rest when the vehicle is in a stopped condition or otherwise not in motion). In general, battery parameters 151 reflect time-variable patterns of battery 112 that naturally occur during normal operating use of electrical device 110, whereby the battery parameter behavior over time is not caused intentionally by a user or an external source intervening into a normal operation of battery 112 or electrical device 110.

System 105 may be configured to operate continuously during the operation of electrical device 110, and/or be activated by an external trigger or a predetermined event. For example, system 105 may be activated by a connection or disconnection of a charger and/or by the activation of an electrical component coupled to electrical device 110 (such as a battery management system, an electronic control unit, a power adapter, and the like). In another example, system 105 may be activated by an ignition of electrical device 110, such as by turning on of an EV, HEV or PHEV. In a further example, system 105 may be activated when battery 112 enters operation to provide power, such as for powering an EV, HEV or PHEV when driving.

Battery parameters 151 measured by parameter detectors 114 may be considered “primary parameters”, which refers herein to electrical parameters measured directly from battery 112 during normal operation of battery 112 in electrical device 110, such as naturally occurring values or time-variable patterns of DC current, DC voltage, SOC and temperature during the device operation.

Battery parameters 151 measured over time (i.e., time-variable parameters) may include information relating to a temporal variation of an electrical parameter and the functional form of a DC electrical signal profile. For example, primary battery parameters 151 may include a temporal voltage profile characterized in functional form by at least one of: an instantaneous IR voltage drop, a subsequent double-layer-charging phase, and a subsequent Faradaic reaction phase. In another example, primary battery parameters 151 may include a temporal current profile characterized in functional form by at least one of: a low polarization region in which the current is linear with the voltage, and a high polarization region in which the natural logarithm of the current is linear with the voltage. In a further example, primary battery parameters 151 may include a temporal current profile characterized by at least one of: an instantaneous change in current; and a subsequent progressive change over time. In yet another example, primary battery parameters 151 may include a temporal current profile characterized by a functional form of current as a function of battery operation. The behavior of the current and the voltage may be constant or non-varying during certain periods of battery operation.

Data collection of primary battery parameters 151 may be implemented for a certain number of data recording points (e.g., 300 points overall), or for a certain time period. Primary battery parameters 151 may be acquired at a fixed rate (i.e., a set number of measurement readings per unit time, such as 10 or 1000 readings per second). Further alternatively, the data collection rate may be linked to a certain change in at least one parameter relating to the operation of battery 112 or electrical device 110, such as a predetermined change in the voltage or current (such as, e.g., a data acquisition for each change of 1 mV for voltage or 1 mA for current). Data collection may be performed in real-time during normal operation of battery 112 and electrical device 110.

A timestamp for each collected battery parameter (such as voltage and current) may be recorded. The timestamp may be represented as, for example: absolute time (i.e., from the start of electrical device operation); relative time (i.e., from the start of the monitoring session), or standard time (i.e., actual local time independent of the electrical device operation). Units of measurement for any type of recorded data may be predetermined or modified in real-time by system 105, and/or established by a user or an external source.

Battery parameters 151 are received and processed by data analysis module 125. In particular, data analysis module 125 applies at least one processing model to the measured battery parameters 151 to extract related output parameters 152, 154. The processing may be performed substantially in real-time during the battery powered operation of electrical vehicle 110. The output parameters 152, 154 may generally be considered “secondary parameters”, where a “secondary parameter” refers to a parameter derived from one or more primary parameters (measured directly from battery 112), or from a combination of at least one primary parameter and at least one secondary parameter.

A secondary parameter may include a parameter derived by applying at least one mathematical operation or equation to at least one primary parameter, and optionally to some combination of primary parameters and secondary parameters, where such mathematical operations or equations may be applied in any sequence or combination, including for example at least one of: logarithm, natural logarithm, power, root, inverse, exponent, derivative (with respect to time, capacity, SOC or another primary parameter), inverse of derivative (with respect to time, capacity, SOC or another primary parameter), trigonometric functions (e.g., sine, cosine, tangent, cosine, cotangent), integrals, second or higher level derivative (with respect to time, capacity, SOC or another primary parameter), linear regression of a functional form of a primary parameter profile, division, multiplication, subtraction, addition, curve fitting including polynomial curve fitting, and other mathematical operations known in the art. Secondary parameters may also result from applying at least one mathematical, physical, or chemical constant or coefficient to at least one primary parameter or secondary parameter.

According to one exemplary aspect, the processing model is based on an electronic circuit including a network of resistors and capacitors that may be connected in various combinations and is referred to herein as a “resistors-capacitors (RC) model”, generally referenced 142. RC model 142 may be configured to apply one or more mathematical operations, equations and/or algorithms on the input data. Non-limiting examples of such mathematical operations and equations may include: parameter fitting, Hessian optimization, and curve fitting, including various applicable methods or techniques, such as: least squares, recursive least squares, polynomial fitting, exponential fitting, approximations of voltage and current patterns, time series, and the like.

The input parameters fed to RC model 142 may include: voltage and/or current measurements of the battery or at least one battery cell; a state of charge (SOC); battery temperature; ambient temperature; and data acquisition timestamps for each measurement. Initial estimations of input parameters may be obtained by various means, such as from estimated values; from values based on specifications of the battery or cell; and from quantitative electrochemical equations. RC model 142 may be configured to determine if certain temporal changes in current or voltage may be used to calculate certain output (secondary) parameters. RC model 142 may further be configured to determine a validity of calculated output parameters for determining an SOR of battery 112, as will be discussed further hereinbelow.

RC model 142 may apply various types of filtering of input current and voltage. RC model 142 may apply multiple equations for a voltage input. A mathematical operation or equation may be applied over multiple iterations, such as assuming small parameter changes. For example, small steps (changes) from previous values may be tested over several iterations, to determine an optimal parameter set to maintain. In another example, a stochastic iteration process may be applied, such as by testing one small step (change) in a random direction and maintain an optimal value, or alternatively by testing different directions according to a deterministic sequential pattern.

The application of RC model 142 may be particularly useful when primary battery parameters 151 includes current and voltage patterns that are not: (a) transitions between different levels of constant current (or transitions between current (charge or discharge) and zero current); or (b) transitions between different levels of constant voltage during discharge or charge (or operating voltage and either rest voltage or open circuit voltage); or (c) transitions between different levels of constant power during charge or discharge (including zero power). RC model 142 may be particularly applicable in dynamic power situations of current and voltage patterns, such as when electrical device 110 operates with dynamic power conditions, such as during a driving operation (e.g., of an EV) or a charging operation (e.g., adaptive charging conditions when the charging utilizes transitions between non-constant levels of current and/or voltage). The application of RC model 142 may also be particularly applicable when the data acquisition rate of the battery signal change over time is relatively slow, such as a rate of about 10 to 50 Hz.

RC model 142 may be applicable when there is a sharp transition in primary battery parameters 151, or when there is a non-sharp transition. A “sharp transition” may be considered one where time for a battery parameter (e.g., current or voltage) to transition from a first value level to a second value level is about ten times shorter than the data acquisition rate. For example, RC model 142 may be applied when there are no sharp current steps or voltage steps in battery parameters 151, where a step is a sudden increase or decrease in value of the current or voltage. RC model 142 may match a current-voltage (I-V) behavior around current or voltage changes substantially well with the same (or similar) parameters that may be matched with ideal steps. A “non-sharp transition” may be considered a transition that is characterized by a slope, where a slope is a rate of change (derivative with respect to time) of a primary parameter, with the transition time less than about 20 times the data acquisition rate. Alternatively, a non-sharp transition may be a transition occurring over multiple small steps between the start and end of the transition.

Primary battery parameters 151 undergoes processing by RC model 142 to derive one or more secondary battery parameters 152. Secondary parameters 152 (also referred to as “output parameters”) may include values calculated from measured voltage or current in at least one measurement period, such as during at least a portion of an operating period of electrical device 110, such as during a complete operating period. Output parameters 152 may include parameters extracted from a measured voltage profile, such as: internal resistance; double layer capacity; faradaic reaction resistance; and kinetic parameters. Output parameters 152 may include parameters extracted from a measured current profile, such as electrode surface area. Further examples of output parameters 152 may include but are not limited to: time constant for a double layer charging or discharging phase (transition time Tᵣ); Sand equation parameters; change in voltage during double layer charging or discharging; change in voltage during a Faradaic reaction phase of a current step; reaction resistance (Rrxn); exchange current density (iₒ); Tafel slope (βa or βc); reaction polarization (Rpol); current deviation value (i_{d}); current changes as a result of changes in voltage; derivatives and second order derivatives with respect to time or SOC of a voltage or current; functional form of a voltage scan; derivatives with respect to time of current; Randles-Sevcik equation parameters; voltage changes as a result of changes in current; Cottrell equation parameters; and active surface area of battery electrodes.

According to another aspect of the present disclosure, the processing model is based on a machine learning (ML) model, generally referenced 144. ML model 144 may be configured to process primary battery parameters 151 to extract one or more secondary parameters 154. ML model 144 may utilize machine learning techniques to determine SOR indicative output parameters and to identify patterns and classification categories. For example, ML model 144 may apply at least one neural network, such as a regression network and/or a classification network, for processing and modeling relationships between inputs and outputs for machine learning, relating to predicting a time from detection of an internal fault (IF) to the onset of a SCDH. More generally, the data analysis may utilize any suitable machine learning supervised learning process or algorithm known in the art, including but not limited to: an artificial neural network (ANN) algorithm, such as a convolutional neural network, a recurrent neural network (RNN), or a deep learning algorithm; a classification or regression analysis, such as a linear regression, a logistic regression or other regression model; a decision tree learning approach, such as a random forest classifier; a fuzzy algorithm; a genetic algorithm; a cellular automata algorithm; an immune network algorithm; a rough-set algorithm; and/or any combination thereof. The data analysis may utilize any suitable tool or platform, such as publicly available open-source machine learning or supervised learning tools.

ML model 144 receives primary parameters 151 collected during a normal operation of electrical device 110 and derives one or more secondary parameters 154. The input parameters fed to ML model 144 may include: voltage and/or current measurements of the battery or at least one battery cell; a state of charge (SOC); battery temperature; ambient temperature; and data acquisition timestamps for each measurement. Initial estimations of input parameters may be obtained by various means, such as from estimated values; from values based on specifications of the battery or cell; and from quantitative electrochemical equations. ML model 144 derives secondary parameters 154, which may include parameters extracted from a measured voltage profile or from a measured current profile in at least one measurement period (such as exemplary secondary parameters 152), such as during at least a portion of an operating period of electrical device 110. Examples of secondary parameters 154 may include but are not limited to: time constant for a double layer charging or discharging phase (transition time Tᵣ); Sand equation parameters; change in voltage during double layer charging or discharging; change in voltage during a Faradaic reaction phase of a current step; reaction resistance (Rrxn); exchange current density (iₒ); Tafel slope (βa or βc); reaction polarization (Rpol); current deviation value (i_{d}); current changes as a result of changes in voltage; derivatives and second order derivatives with respect to time or SOC of a voltage or current; functional form of a voltage scan; derivatives with respect to time of current; Randles-Sevcik equation parameters; voltage changes as a result of changes in current; Cottrell equation parameters; and active surface area of battery electrodes.

At least one activation function (also known as a transfer function) may be used in a regression neural network to transform the input (primary parameters 151) into an output (secondary parameters 154). The input may undergo pre-processing in accordance with a particular type of neural network (or other machine learning approach) applied by ML model 144 to ensure effective operation thereof. For example, the input data may be normalized to scale the data into an acceptable range for the neural network. ML model 144 may be configured to determine if certain temporal changes in current or voltage may be used to calculate certain output (secondary) parameters. ML model 144 may further be configured to determine a validity of calculated output parameters for determining an SOR of battery 112, as will be discussed further hereinbelow.

According to an aspect of the present disclosure, at least one primary parameter and/or secondary parameter may include a time series of a change, and the time series may be converted to a small set of numbers that serves as an input to a neural network applied by ML model 144. The conversion numbers may include, for example, a delta (change) of the current or voltage in transitions to or from a constant power mode. In such a case, the input parameters for a matrix table (described hereinbelow) may be a number for the particular delta value, and the output time to SCDH may be the time duration for the IF to develop into a SCDH event for that particular test.

Furthermore, ML model 144 may also consider a progression or trend of an input data parameter over a period of time, rather than merely considering a single input data value, and may utilize such a trend for assessing a safety state with the neural network. From a large dataset, attributes of a trend may be converted to a numerical value, such as a derivative value, which may be applied as an input to a neural network of ML model 144.

ML model 144 may be generated during a preliminary training stage. Specifically, a training dataset that includes a large collection of reference samples of primary battery parameter data is fed into a training process that utilizes machine learning techniques to identify patterns and create models for extracting secondary parameters that can be applied on new input datasets. The training process may produce mapping functions that can be used for classifying additional instances of new datasets (primary parameter data) according to relevant classification criteria.

A training dataset may include data relating to “safe cells” (i.e., without an IF), and may further include data for cells having varying degrees of IF. Such a training dataset may enable a neural network-based training process to identify and differentiate between a “safe cell” (i.e., that is unlikely to develop a SCDH) and an “unsafe cell” (i.e., that is likely to develop a SCDH), and to detect varying degrees of hazard of a cell. In one example, a second dataset may be provided to validate the training of the generated ML model 144 and for fine-tuning. In another example, a testing dataset including information of known behavior of an IF progressing to a SCDH event may be applied to obtain a final evaluation of a neural network-based analysis of ML model 144, and to ensure that ML model 144 is properly trained. In general, various combinations of training datasets, validation datasets, and final evaluation datasets may be used.

To obtain a training dataset, tests may be performed on battery cells for a large set of initial stages of an IF, to obtain primary parameters at such initial IF stages. Different stages of an IF may correspond to different times required by the IF to develop into a SCDH, which may be different when developing under different cell conditions. Cell conditions may include but are not limited to: ambient temperature during cell operation, cell temperature, cycle number, calendar age, for how long and at what temperature the cell was stored prior to use, and SOC of cell. Multiple training datasets may be collected, each dataset being respective of a different cell condition.

To build a training dataset, at least one primary parameter may be measured, from which secondary parameters may be derived. For example, a matrix of “N” rows by “n” columns may be formed. Using an example of N=10 rows, the first 9 rows in each column are the inputs, corresponding to primary battery parameters and optionally secondary parameters, which may be obtained at a same specific time. The 10th row is the output, namely the time to a SCDH event from a given IF stage. The value “n” of the number of columns represents the different experiment tests that are run. In one example, an experiment may be run with different cells with the same, similar or different initial conditions of an IF. In another example, an experiment may be run for a particular cell as the cell degrades at different times during the development of the IF condition. A combination of the aforementioned examples may also be utilized. Accordingly, test runs may be applied for different cells with the same or different initial condition of the IF, or the same cells at different times during the development of the IF towards becoming a SCDH. Increasing the number of experiments that are conducted (i.e., increasing the value of “n”) may enhance the accuracy of the output results.

ML model 144 may process different combinations of input data parameters, such as by grouping training datasets for test runs on the same cell but at different IF initial conditions (including healthy battery conditions), or on different cells with similar or different IF conditions. An output time of various combinations of parameters may be compared to the actual behavior of a known operation of a physical battery cell where an IF develops into a SCDH event, such as to determine an optimal combination of parameters to apply in a classification neural network processing for forecasting the time to a SCDH for an IF for a particular cell condition. Different cell conditions may require a customized set of parameters for enhancing accuracy of the output, where a selected (e.g., optimal) parameter set for a first cell condition may be different from a selected (e.g., optimal) parameter set for a second cell condition.

It is noted that datasets of primary parameter measurements may require large storage space, and therefore such datasets may be processed to produce one or more secondary parameters to reduce storage requirements. During operation of a battery cell, primary parameter data may be compared to a library of attributes of secondary parameters, for assessing a safety state of the cell. Such a library of attributes may also be used for deriving a time forecast to SCDH (e.g., using a regression neural network), or for determining whether a SCDH will or will not occur within a predefined time period (e.g., using a classification neural network).

In one example, ML model 144 applies processing based on a regression neural network. An objective of a regression network-based model may be to generate a prediction for the time required for an IF at a particular developmental stage (initial condition) to transform into a SCDH event. This may be accomplished by using cell or battery parameters as input for a regression network, the cell/battery parameters being selected from any combination of primary parameters, secondary parameters and other cell/battery attributes (e.g., capacity, volume, weight, number of cells in a module or battery pack, number of modules in a battery pack, and the connectivity (series or parallel or a combination) of such cells and modules and packs). For example, an output of such a regression network may include the time required for an IF to transform into a SCDH, where the time may be expressed as a numerical value within a continuous range of values. For another example, an output of such a regression network may include a probability metric of an IF transforming into a SCDH. The output may be filtered to eliminate results that do not meet some predefined threshold value.

In another example, ML model 144 applies processing based on a classification neural network. An objective of a classification network-based model may be to generate a prediction for whether a battery cell will develop a SCDH within a certain time period, such as one week. In this case, an output of such a classification network may include a Boolean response represented as binary values (zero or one) corresponding to “true”/“false”, or “will not develop SCDH”/“will develop SCDH”.

In one example, a classification network model may receive as an input a functional form of at least one primary parameter, such as current or voltage as a function of time (or a function of a different parameter), for determining whether an IF will develop into a SCDH within a specified time period, or alternatively for determining the amount of time required for an IF to develop into a SCDH event. One class of such a functional form may include functional forms belonging to healthy battery cells, while another class may include functional forms belonging to battery cells with an IF. A training dataset for each class may include a group of cases, each case containing values for a range of at least one input parameter and at least one output parameter.

One type of training dataset may include a shape of a current curve and a voltage curve at specific times during battery operation, where battery operation may include modes of charge, discharge, open circuit and rest. Such data may include shapes of current/voltage curves corresponding to healthy cells and those corresponding to hazardous cells (i.e., having at least one IF). Various attributes of the shape may be used to associate a particular shape with a particular safety assessment of the cell. Examples of such attributes may include: slope of current or voltage as a function of time, integral area formed by the curve, waveform, first derivative of current or voltage with time, second derivative of current or voltage with time, and the like.

In one example, RC model 142 and ML model 144 may be connected serially, and ML model 144 may be applied subsequent to a processing of RC model 142.

Values and changes of secondary battery parameters 152, 154 may be used to determine a state of risk (SOR) of battery 112. Each output parameter 152 ,154 may be associated with a threshold or control value corresponding to a healthy baseline condition of the battery. The threshold (baseline) value may be established in various ways. For example, a baseline may be predefined (e.g., stored in database 126 ), such as based on offline testing of a representative group of healthy cells using real or simulated discharge profiles (and optionally damaged cells as well), where parameter values calculated from such tests are associated with cells or batteries of that type. Alternatively, a threshold value may be established for a particular cell or battery based on parameter values obtained during an initial cycle of the cell/battery itself (i.e., the initial cycle values may be used as a self-reference for values of secondary parameters 152, 154). A threshold value may also be manually programed, such as by an end-user or an operator of device 110.

A threshold (baseline) value may be established by analyzing initial cycles of a cell/battery, such as based on a change in slope, and/or an absolute value of a calculated output parameter 152, 154. Such analysis may be used to differentiate between changes in parameter values due to natural ageing of the cell/battery on the one hand, and safety risks on the other hand (i.e., a trend analysis). Alternatively, cells or batteries may be extensively cycled in order to determine baseline values for a given parameter in view of their development over a cycle life.

According to an aspect of the present disclosure, a baseline matrix may be established. For example, a baseline matrix may be represented as a three-dimensional (3×3×3) array, where a first index includes 3 ranges of SOC, a second index includes 3 ranges of battery temperature, and a third index includes 3 extents of cycle life. For example, for SOC: a first (upper) range is between 80%-100% SOC; a second (intermediate) range is between: 20%-80% SOC; and a third (lower) range is between 0%-20% SOC, for battery temperature: a first range is below 0 degrees Celsius (C); a second range is between 0-45° C.; and a third range is above 45° C., and for cycle life (depending on the on the nominal maximum specified cycle life): a first (lower) range is up to 30% of the specified nominal cycle life at nominal conditions; a second (intermediate) range is between 30% to 80%; and a third (higher) range is above 80%.

Each individual secondary parameter 152,154 may be associated with a respective SOR. Several techniques may be applied for reducing or avoiding false positives and false negatives for determining SOR. One technique may be based on the number of parameters used to trigger a SOR level indicating a positive determination of a battery fault, i.e., a “fault found (FF)” indication. When high precision data is available, then at least two parameters indicative of an FF may be required to trigger an FF-SOR determination. When low precision for determining SOR is sufficient, then a single parameter indicative of FF may be sufficient to trigger an FF-SOR determination. Another technique may be to require that a parameter register a potential fault found (PFF) or fault found (FF) indication at least twice within a given measurement period in order to be classified as a PFF-SOR or FF-SOR determination, or alternatively for at least two consecutive measurements within the measurement period. A trend analysis (e.g., analyzing dynamic changes in a calculated output parameter) may also be applied to minimize false positive and false negative determinations.

Data analysis module 125 compares values of secondary parameters 152, 154 to reference thresholds (such as a baseline matrix) to determine a state of risk (SOR) of battery 112. An SOR may be determined for each one of (or selected ones of) secondary parameters 152, 154. In one exemplary aspect, an overall battery SOR may be determined by evaluating a group of secondary parameter SORs (e.g., by evaluating all SORs determined for all secondary parameters 152, 154). When establishing baselines, each secondary parameter 152, 154 may be associated with one or more threshold values respective of different SOR categories or levels. For example, SOR categories may include the following:
1. No Fault Found (NFF): no defects detected.
2. Suspicious but NFF: an identified parameter value is abnormal relative to a natural degradation but is still within NFF range.
3. Potential Fault Found (PFF): limited degradation, no pending risk; triggers battery corrective measures; safety degradation beyond natural fade but without imminent risk.
4. Significant degradation that could create a SCDH; may trigger alert or limited battery corrective measures.
5. Fault Found (FF): significant defect or risk of significant defect, early warning of thermal runaway or SCPC; may trigger alert and high urgency battery corrective measures and user protection measures.

The different SOR levels may be further categorized into multiple “sensitivity levels”, which may determine whether an alert is issued and/or corrective measures implemented. An example of a sensitivity level categorization based on SOR levels is as follows:

TABLE 1

| | Repeat | |
|---|---|---|
| Sensitivity | function | Overall cell SOR based on output |
| Level | activated | parameter SOR condition |
| High | No | Sufficient for only one output parameter to |
| | | be PFF or FF. |
| | | Whichever output parameter is indicative |
| | | of PFF/FF is SOR used for overall cell |
| | | SOR |
| Medium | Yes | Sufficient for only one output parameter to |
| | | be PFF or FF. |
| | | Whichever output parameter is indicative |
| | | of PFF/FF is SOR used for overall cell |
| | | SOR |
| Low | Yes | If SOR for all output parameters is PFF |
| | | then overall SOR is PFF. |
| | | If SOR for all output parameters is FF then |
| | | overall SOR is FF. |
| | | If SOR for output parameters is |
| | | combination of NFF and PFF, then overall |
| | | SOR is NFF. |
| | | If SOR for output parameters is |
| | | combination of NFF and FF, then overall |
| | | SOR is NFF. |
| | | If SOR for output parameters is |
| | | combination of PFF and FF, then overall |
| | | SOR is PFF. |

The sensitivity levels of SOR categories may be adjustable and modified, for example, based on characteristics of battery 112 or electrical device 110 or the operating environment. For example, a low cycle life or fresh battery may be designated with a low sensitivity, whereas a highly cycled or aged battery may be designated with a high sensitivity. The SOR level for each secondary parameter may be set, such as based on the number of times an SOR category (e.g., PFF or FF) is determined within a set time interval. Furthermore, an overall battery SOR sensitivity may be adjustable based on the number of times a secondary parameter SOR category (e.g., PFF or FF) is used in the determination. For example, for a high sensitivity case, only one FF from a single secondary parameter is sufficient, whereas for a low sensitivity case, all secondary parameters-all secondary parameters need to register an SOR category of PFF or FF. Adjusting a sensitivity level of the SOR determination may facilitate the minimizing of false positives.

After obtaining output parameters 152 (using RC model 142) and/or output parameters 154 (using ML model 144), data analysis module 125 processes output parameters 152, 154 to generate SCPC analysis 155. Data analysis module 125 may identify at least one marker that is indicative of an IF (or SCPC) of battery 112. At least two distinct markers, or a single marker at multiple times, derived from primary parameters 151 and/or secondary parameters 152, 154, may be compared for consistency to mitigate false negative and/or false positive measurements, and may be used to obtain further comprehensive information about the condition of the cell or battery.

SCPC analysis 155 may include an indication of a likelihood of SCDH, such as based on an SOR category. For example, SCPC analysis 155 may include a determination of an SOR for battery 112, such as No Fault Found (NFF), Potential Fault Found (PFF), or Fault Found (FF). Application 134 may issue a notification or alert 157 relating to a determined short circuit derived hazard based on the SCPC analysis 155. For example, an alert 157 may be issued if a determined likelihood of the SCDH exceeds a predefined threshold level, such as if the SOR is determined to be PFF category or FF category.

Data analysis module 125 may be able to discriminate between a spectrum of safety risk states of battery 112, ranging from completely healthy to urgent dangerous and states in between (such as a defective cell but not an imminent danger). In one example, a healthy pattern and/or a dangerous and/or at least an intermediate pattern is stored as a reference or baseline value. A comparison may be made between the reference and one or more primary parameters or secondary parameters to check for a fit. For example, a delta difference may be calculated between the two and the magnitude of the difference may be used for determination of a SOR.

An alert 157 may be displayed on user interface 138 of user device 130, such as via a visual indication (e.g., displaying text, markings, symbols, colors, and/or graphical information) and/or an audible indication (e.g., alarms, beeps, buzzers, bells, ringtones). Alert 157 may be sent from application 135 to at least another destination, such as to another user device 130 associated with a different user, or to a service center or monitoring station or operator associated with electrical device 110. Alert 157 may also be sent to a cloud service, a remote internet application, or a web-based communication network.

More generally, application 135 may provide a report on user interface 138 relating to the monitoring of battery 112. The report may include a visual representation of information in SCPC analysis 155, such as derived secondary parameters 152, 154, SOR determinations, information about electrical device 110 and/or a user thereof, and other relevant data. The report may include characteristics of a SOR determination, such as a priority level (e.g., reflecting a severity or urgency of an internal cell fault) or a confidence level (e.g., reflecting a reliability of the SOR determination). The report may further include various statistics associated with the SOR determination, such as historical data relating to battery 112 and/or electrical device 110 obtained at previous dates and times, or SOR data obtained for same or different types of batteries or electrical devices. The information and statistics may be presented over a selected duration, such as depicting dynamic changes over time.

Application 135 may also provide recommendations for suggested actions or corrective measures based on SCPC analysis 155, for mitigating a potential SCDH of battery 112. For example, a suggested corrected measure may be based on a severity level of alert 157, which may relate to a determined SPCP level and/or a determined SOR category. A corrective measure may be implemented by one or more of: electrical device 110 (e.g., by activating a protection module incorporated in device 110); by a user; or by a battery management system. Examples of corrective measures may include: activation of a thermal management system; a limitation on operating voltage or current either during discharge use or charge use; turning off electrical device 110; isolation of at least one cell or module in battery 112; and activation of a fire suppression or extinguishing system. Another example of a corrective measure may include applying a specific discharge voltage to a cell or battery, such that the applied discharge voltage oxidizes at least a portion of lithium plating in the cell or battery. A further example of a corrective measure is to maintain the battery in an open circuit (zero current) or rest state (electrically isolated or disconnected from the device) for a period of time which allows equilibration, migration or transport of the lithium metal plated on the anode into the anode structure and possible further reaction. Corrective measures can include any type of passive or active (1) action, (2) use of a material either (a) pre-included at the time of assembly or insertion of the battery or cell into the device, in the battery or cell, or use around cells, or between cells in a group of cells, module or pack, or (b) applied after such assembly or insertion into the device, or (3) process intended to mitigate or prevent the occurrence of a short circuit derived hazard (SCDH). Application 135 may determine and present recommendations directed to optimize user criteria.

It will be appreciated that the disclosed aspects may allow for providing early detection and alerting of a potential short circuit derived hazard in a lithium battery powered electrical device. The alert may be provided before the onset of an internal short circuit in the battery, enabling timely implementation of a corrective action to mitigate or prevent the short circuit derived hazard (e.g., combustion). A state of risk of the battery may be determined by identifying markers of an IF or short circuit precursor conditions in battery 112, such as based on secondary parameters derived from primary battery parameters obtained during operation of electrical device 110. The IF and SCPC markers and state of risk information may be determined based on machine learning models, such as neural network-based models, such as using a remote cloud-based computing platform, which may undergo dynamic training using large and diverse datasets, to continually enhance the prediction results. The disclosed aspects may utilize existing wiring and electronic infrastructure for implementation, without requiring additional dedicated hardware components such as added sensors, wiring and hardware for passive battery monitoring. The battery parameters may be readily obtained using standard electrical parameter measurement components (such as for measuring current, voltage, and state of charge). As a result, the disclosed aspects may be relatively low cost, easy to install, maintain and upgrade, and may not necessitate additional weight or volume. Moreover, the disclosed aspects may provide for automated battery safety monitoring, which may be applied to rechargeable lithium batteries of various types, designs and configurations, as well as various battery-powered electrical devices, providing versatility and flexibility. Elements of the disclosed aspects may be embedded into semiconductor integrated circuit chips such as microprocessors and ASIC chips, and/or incorporated into software in existing instruments or components that check, manage or monitor batteries, including but not limited to: chargers (wired or wireless), charging stations, power adapters (wired or wireless), battery management systems, electronic control units, computers, and the like).

According to one aspect, electrical device 110 may be an electric, hybrid or plug-in hybrid vehicle. For example, data analysis module 125 may be embodied at least in part as a software program in the system electronics of a vehicle (e.g., battery management system (BMS) electronics, microcontroller chip, battery control unit, power management unit, microprocessor), such as in an ASIC or processor chip, or as part of the operating system software. The protocols may acquire DC current and DC voltage, as well as other battery, device, and/or user data, utilizing existing wireless, wirings, and BUS connections between the battery and a control unit. Temperature measured via usual installed sensors may be used for reference calibration and as an auxiliary input to the analysis. The disclosed processes may be integrated with the main system software to access DC electrical, SOC, and temperature information that may be routinely collected in any case.

The following information may be accessed by the data analysis from the BMS for use in setting protocols: battery mode at time of data acquisition (charge, discharge, open circuit, or rest), and if accessible fuel gauge capacity, cycle number, state of health, and state of charge. Connectivity may be implemented to provide battery authentication data, such as battery make, cell type, nominal capacity, serial number, batch number, and identifying codes of the vehicle. The disclosed aspects may not interfere with regular operation of nor prolong the typical BMS program cycles. Data acquisition may be done with both single task and multi-tasking processors. With single task processors, the disclosed processes may be harmonized, synchronized or interleaved with tasks run by the MCU.

Collected data may be stored and analyzed onboard or transferred to an auxiliary processing or storage unit or a cloud server 120 for subsequent downloading for analysis by server computers. Data may be buffered prior to being accessed by an on-board algorithm or transmission to cloud server 120. Signal processing algorithms may be stored onboard the BMS, or remotely (such as at cloud server 120), or at end user computing device 130. Data storage may be periodically refreshed or archived. In one aspect, analysis of the data by processing models 142, 144 may be performed post-transmission after measurement is completed (i.e., not in real-time), and may be performed offline after testing is completed. Results may be archived on onboard memory or uploaded to cloud server 120 or a remote device for storage, or subsequently downloaded to a service center where analysis may be performed. Historical data can be used for optimizing the processes for particular identified usage profiles on an individual or crowd-sourced basis.

According to another aspect, electrical device 110 may be a mobile computing device. For example, an application operating on a mobile device may collect in real-time cell operating data including current, voltage, temperature, and operation mode, and uploads the information to cloud server 120. The data in cloud server 120 may be processed, using machine learning based predictive models. An application may acquire relevant battery parameter data, upload the batter data to a secure cloud server 120 for storage, and be retrieved by a server computer for analysis. The device application may be applied in a Software-as-a-Service (SaaS) business model, by collecting a large amount of crowdsource data for enhancing predictive analytic capabilities. The application may be available for downloading or pre-embedded at the time of device assembly, to a mobile computing device, such as a smartphone or tablet computer, which may operate using various platforms, including but not limited to: iOS, Windows and Linux. The application may collect battery operating data of the mobile device, such as voltage, current, temperature (both environmental and/or skin temperature of the cell), mode (charge, discharge, rest, open circuit) over time, a unique identifying code of the mobile device, and battery details (e.g., battery serial number, batch code, battery type, battery capacity, battery voltage) authentication details of the device and/or battery or battery cell, and background information about the test which may be provided by the user.

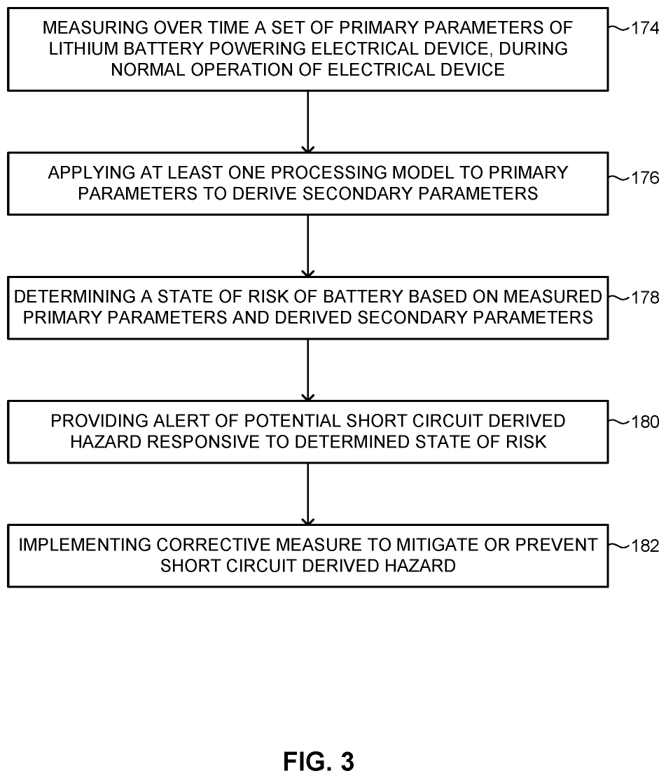

Reference is now made to FIG. 3, which is a flow diagram of a method for detecting a safety hazard of a rechargeable lithium battery powering an electronic device, operative in accordance with an aspect of the present disclosure. In procedure 174, a set of primary battery parameters of a lithium battery powering an electrical device is measured over time, during a normal operation of the electrical device. Referring to FIGS. 1 and 2, battery parameter detectors 114 measures time-variable primary parameters 151 of at least one cell of battery 112 over a measurement time period during a normal operation of electrical device 110. The measured primary parameters may include: DC voltage; DC current; SOC; temperature of battery 112; ambient temperature; and measurement timestamps. Primary parameters 151 are obtained when electrical device 110 is in normal operation, such as during a driving state for an electric vehicle or during a charging or discharging condition.

In procedure 176, at least one processing model is applied to the primary parameters to derive secondary parameters. Referring to FIGS. 1 and 2, data analysis module 125 receives and processes time-variable battery parameters 151, such as via RC model 142 and/or via ML model 152, and generates secondary parameters 152, 154.

In procedure 178, a state of risk of the battery is determined based on the measured primary parameters and the derived secondary parameters. Referring to FIGS. 1 and 2, data analysis module 125 processes secondary parameters 152, 154 output by RC model 142 and/or ML model 144 to generate SCPC analysis 155. Data analysis module 125 may identify markers indicative of an internal fault and/or a SCPC of battery 112 to determine a state of risk (SOR) of battery 112. The markers may be determined and processed using machine learning generated models. SCPC analysis 155 may include an indication of a likelihood of a SCDH, such as based on a determined SOR category, such as No Fault Found (NFF), Potential Fault Found (PFF), or Fault Found (FF). The SOR may be determined by comparing secondary parameters to respective threshold or baseline values, such as represented in a baseline matrix.

In procedure 180, an alert of a potential short circuit derived hazard is provided responsive to the determination. Referring to FIGS. 1 and 2, user management application 135 provides an alert of a potential SCDH on user interface 138 of user device 130. The alert is provided based on SCPC analysis 155 and the determined SOR of battery 112, such as if the determined SOR is in at least one predefined SOR category, the SOR is determined to be PFF category or FF category. Application 135 may further provide a general report relating to the safety monitoring of battery 112, such as information relating to secondary parameters 152, 154, SOR determinations, electrical device 110, characteristics and statistics (priority level, confidence level) and historical data.

In procedure 182, a corrective measure to mitigate or prevent a short circuit derived hazard is implemented responsive to the determination. Referring to FIGS. 1 and 2, at least one action or corrective measure to mitigate or prevent a SCDH of battery 112 is implemented, such as by electrical device 110, by a user, and/or by a battery management system. The corrective measure may be implemented following a directive provided by user management application 135 based on SCPC analysis 155 and the determined battery SOR. For example, a suggested corrected measure may be based on a severity level of alert 157, which may relate to a determined SPCP level and/or a determined SOR category.

The method of FIG. 3 may be implemented in an iterative manner, such that at least some of the steps are performed repeatedly and/or continuously. According to an aspect of the present disclosure, at least some of the method steps may be performed substantially in real-time during operation of a battery-powered electrical device. In particular, measurement of primary parameters (step 174); processing of primary parameters to derive secondary parameters (step 176); determining a state of risk of the battery (step 178); providing an alert of a potential SCDH (step 180); and/or implementing a corrective measure (step 182) may be performed substantially in real-time during normal operation of electrical device 110.

The present invention is applicable to battery safety monitoring in a wide variety of applications. In particular, the disclosed safety monitoring method may be applied to any rechargeable lithium battery powered device, product or system in any technical field, including but not limited to: consumer electronics (e.g., mobile phones; laptop computers; tablet computers; e-book readers; smart-watches or other wearable electronic products; and the like), vehicles (e.g., aircrafts; land vehicles; electric trains; electric-vehicles (Evs), including pure Evs, hybrids and plug-in hybrids; electric buses; electric carts; electric wheel chairs; electric heavy equipment including forklifts; electric boats and submarines and other marine vessels, electric-bicycles (e-bikes); electric-scooters (e-scooters), UAV drones); communication devices (e.g., radios, two-way radios, receivers, transmitters, transceivers, and the like), electrical equipment (e.g., power tools; electronic cigarettes (e-cigs); medical devices, including implantable devices, and facilities for energy storage (e.g., charging stations, grid energy storage systems, solar panel energy storage, wind turbine energy storage, hydroelectric and wave and tidal energy storage; satellites.

While certain aspects of the disclosed subject matter have been described, so as to enable one of skill in the art to practice the present disclosure, the preceding description is intended to be exemplary only. It should not be used to limit the scope of the disclosed subject matter, which should be determined by reference to the following claims.

What is claimed is:

1. A method for safety monitoring of a rechargeable lithium battery powering an electrical device, the method comprising the steps of:
measuring over time primary parameters of the battery, during a normal operation of the electrical device;
processing the measured primary parameters to derive secondary parameters; and
determining a state of risk (SOR) of the battery based on the measured primary parameters and the derived secondary parameters, during the normal operation of the electrical device.

2. The method of claim 1, wherein the primary parameters comprises: a direct current (DC) current measurement; a DC voltage measurement; a state of charge (SOC) measurement; and a timestamp of each measurement.

3. The method of claim 2, wherein the primary parameters further comprises at least one of: a battery temperature measurement; and an ambient temperature measurement.

4. The method of claim 1, wherein the step of processing comprises at least one selected from the group consisting of:
applying a resistors-capacitors model, configured to apply at least one mathematical operation or equation on the primary parameters; and
applying a machine learning model, configured to apply at least one machine learning process on the primary parameters.

5. The method of claim 1, wherein the step of determining a state of risk (SOR) comprises comparing at least one of the derived secondary parameters with a respective at least one baseline value reflecting a baseline condition of the battery.

6. The method of claim 5, wherein the step of determining a SOR comprises determining a plurality of secondary parameter SORs, each of the secondary parameter SORs being associated with a respective one of the derived secondary parameters, and determining an overall battery SOR based on the plurality of secondary parameter SORs.

7. The method of claim 1, further comprising a step selected from the group consisting of:
providing an alert of a potential short circuit derived hazard, responsive to the determined state of risk; and
implementing at least one corrective measure to mitigate or prevent a short circuit derived hazard, responsive to the determined state of risk.

8. The method of claim 7, wherein the state of risk comprises a state of risk category selected from the group consisting of: No Fault Found (NFF); Potential Fault Found (PFF); and Fault Found (FF), and wherein at least one of the steps of providing an alert and implementing at least one corrective measure is performed when the determined state of risk comprises a state of risk category of PFF or FF.

9. The method of claim 8, wherein the state of risk is determined in accordance with an adjustable sensitivity level reflective of at least one of: the battery;
the electrical device; and an operating environment thereof.

10. The method of claim 1, wherein the electrical device is selected from the group consisting of: an electrical vehicle (EV); a hybrid vehicle (HV); and a plug-in hybrid electric vehicle (PHEV).

11. A system for safety monitoring of a rechargeable lithium battery powering an electrical device, the system comprising:
at least one battery parameter detector, configured to measure over time primary parameters of the battery, during a normal operation of the electrical device; and
a processor, configured to process the measured primary parameters to derive secondary parameters, and to determine a state of risk of the battery based on the measured primary parameters and the derived secondary parameters, during the normal operation of the electrical device.

12. The system of claim 11, wherein the processor is selected from the group consisting of:
a processor of the electrical device; and
a processor of a cloud computing server, communicatively coupled with the electrical device via a network.

13. The system of claim 11, wherein the battery parameter detector comprises a detector selected from the group consisting of:
a DC current detector, configured to measure a DC current of the battery;
a DC voltage detector, configured to measure a DC voltage of the battery;
a state of charge detector, configured to measure a state of charge of the battery;
a clock, configured to provide a timestamp of each measurement; and
a temperature sensor, configured to measure at least one of: a battery temperature; and an ambient temperature.

14. The system of claim 11, wherein the processor comprises at least one selected from the group consisting of:
a resistors-capacitors model, configured to apply at least one mathematical operation or equation on the primary parameters; and
a machine learning model, configured to apply at least one machine learning process on the primary parameters.

15. The system of claim 11, wherein the processor is configured to determine a state of risk (SOR) based on a comparison of at least one of the secondary parameters with a respective at least one baseline value reflecting a baseline condition of the battery.

16. The system of claim 11, further comprising an application operating on a user computing device communicatively coupled with the processor via a network, the application configured to provide an alert of a potential short circuit derived hazard, responsive to the determined state of risk.

17. The system of claim 16, wherein the system is configured to implement at least one corrective measure to mitigate or prevent a short circuit derived hazard, responsive to the determined state of risk.

18. The system of claim 17, wherein the state of risk comprises a state of risk category selected from the group consisting of: No Fault Found (NFF); Potential Fault Found (PFF); and Fault Found (FF), and wherein at least one of providing an alert and implementing at least one corrective measure is performed when the determined state of risk comprises a state of risk category of PFF or FF.

19. The system of claim 18, wherein the processor is configured to determine a state of risk in accordance with an adjustable sensitivity level reflective of at least one of: the battery; the electrical device; and an operating environment thereof.

20. The system of claim 11, wherein the electrical device is selected from the group consisting of: an electrical vehicle (EV); a hybrid vehicle (HV); and a plug-in hybrid electric vehicle (PHEV).
